(19) United States
(12) Patent Application Publication
(10) Pub. No.: US 2025/0387857 A1
(43) Pub. Date: Dec. 25, 2025

(54) PARTICLE REMOVAL APPARATUS

(71) Applicant: Samsung Display Co., LTD., Yongin-si (KR)

(72) Inventors: Do Sun KIM, Yongin-si (KR); Taek Kyo KANG, Yongin-si (KR); Eu Gene KANG, Yongin-si (KR); Sang Hoon OH, Yongin-si (KR)

(21) Appl. No.: 19/097,495

(22) Filed: Apr. 1, 2025

(30) Foreign Application Priority Data
Apr. 2, 2024 (KR) 10-2024-0044834

(51) Int. Cl. B23K 26/142; B23K 26/14; B23K 26/382; B23K 101/40

(52) U.S. Cl. CPC B23K 26/142; B23K 26/1436; B23K 26/382; B23K 2101/40

(57) ABSTRACT

A particle removal apparatus includes a main body portion through which a laser for machining a workpiece passes and a particle generated from machining the workpiece is suctioned, and a particle collector connected to the main body portion. The main body portion includes a particle inlet through which the particle removal apparatus is configured to suction, a laser inlet through which the laser passes, a particle outlet through which the particle removal apparatus is configured to discharge the particle suctioned into the main body portion, a first flow path connecting the particle inlet and the laser inlet, and a second flow path connecting the first flow path and the particle outlet. The particle collector is connected to the particle outlet and is configured to apply a first suction pressure and a second suction pressure. The first flow path includes a pressure reducing section.

This application claims priority to Korean Patent Application No. 10-2024-0044834 filed on Apr. 2, 2024, and all the benefits accruing therefrom under 35 U.S.C. § 119, the content of which in its entirety is herein incorporated by reference.

### BACKGROUND

### 1. Technical Field

The present disclosure relates to a particle removal apparatus.

### 2. Description of the Related Art

In general, an organic light emitting display device implements color through a principle that holes and electrons injected from an anode and a cathode are re-bonded in a light emitting layer to emit light, and an organic light emitting display device may have pixels with a stacked structure in which the light emitting layer is inserted between a pixel electrode, which is the anode, and a counter electrode, which is the cathode.

Each pixel may be a sub-pixel of any one of a red pixel, a green pixel, and a blue pixel, and a desired color may be expressed by a color combination of these three color sub-pixels. The organic light emitting display device has a structure in which a light emitting layer that emits light in one of red, green, and blue is interposed between two electrodes in each sub-pixel, and a color of one unit pixel may be expressed by an appropriate combination of these three colors of light.

The electrodes and light emitting layer of the organic light emitting display device may be formed through deposition. A thin film with a desired pattern is formed by aligning a mask assembly having pattern holes identical to a pattern of a thin film layer to be formed on a substrate, and further, by depositing a raw material of the thin film on the substrate through the pattern holes of the mask assembly. The pattern hole of the mask assembly may be formed through laser machining in which a hole is perforated by emitting a laser and irradiating the mask assembly with the laser.

### SUMMARY

Aspects of the present disclosure provide a particle removal apparatus capable of effectively removing particle generated when machining pattern holes of a mask assembly.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is a particle removal apparatus including a main body portion through which a laser for machining a workpiece passes and through which a particle generated from machining the workpiece is suctioned, and a particle collector connected to the main body portion. The main body portion includes a particle inlet through which the particle removal apparatus is configured to suction the particle, a laser inlet through which the laser passes, a particle outlet through which the main body portion is configured to discharge the particle suctioned into the main body portion, a first flow path connecting the particle inlet and the laser inlet, and a second flow path connecting the first flow path and the particle outlet. The particle collector is connected to the particle outlet and is configured to apply a first suction pressure to the particle inlet and a second suction pressure to the laser inlet, and the first flow path includes a pressure reducing section configured to reduce the second suction pressure.

The pressure reducing section includes an expansion section in which a cross-sectional area of the first flow path gradually increases from the laser inlet toward the particle inlet, and a contraction section formed consecutively with the expansion section. The cross-sectional area of the first flow path is smaller in the contraction section compared to in the expansion section.

The particle removal apparatus includes a plurality of expansion sections and contraction sections, and the plurality of expansion sections and contraction sections are sequentially disposed alternately with each other.

The pressure reducing section includes a plurality of sections, and the plurality of sections are sequentially disposed from the laser inlet toward the particle inlet.

The plurality of sections have different respective cross-sectional areas.

A cross-sectional area of the first flow path in a section closest to the particle inlet among the plurality of sections is smaller than a cross-sectional area of the first flow path in a section closest to the laser inlet.

A cross-sectional area of the first flow path in a section closest to the laser inlet among the plurality of sections is the same as a cross-sectional area of the laser inlet.

The pressure reducing section is closer to the laser inlet than the particle inlet.

The first flow path is partitioned into a direct connection area directly connected to the second flow path and an indirect connection area indirectly connected to the second flow path through the direct connection area, and the pressure reducing section is disposed in the indirect connection area.

The second flow path includes a pressure reducing member configured to reduce the second suction pressure.

Air outside the main body portion flows into the main body portion through the particle inlet by the first suction pressure, and the particle removal apparatus is configured to discharge the air flowing into the main body portion through the particle inlet to the particle outlet, through a first path passing through the first flow path and the second flow path. Air outside the main body portion flows into the main body portion through the laser inlet by the second suction pressure, and the particle removal apparatus is configured to discharge the air flowing into the main body portion through the laser inlet to the particle outlet, through a second path passing through the first flow path and the second flow path. The pressure reducing member extends from an inner surface of the main body portion forming the second flow path to a connection boundary where the first flow path and the second flow path are connected such that the second path is longer than the first path.

The pressure reducing member extends from an inner surface of the main body portion forming the second flow path, adjacent to the laser inlet.

The pressure reducing member includes a first surface forming a portion of the first flow path, and a second surface forming a portion of the second flow path, and the first surface extends such that an end of the pressure reducing member faces the particle inlet.

The second surface extends from the end of the first surface to the inner surface of the main body portion forming the second flow path.

The second surface is a curved surface.

The second surface is concavely formed toward an outside of the main body portion.

The laser inlet is positioned on a same virtual vertical line as the particle inlet.

The particle inlet is disposed in a lower portion of the main body portion, and the laser inlet is disposed in an upper portion of the main body portion.

The particle outlet is disposed in a higher position than the particle inlet in the main body portion.

The second flow path includes a pressure reducing member configured to reduce the second suction pressure, the pressure reducing member extends from an inner surface of the main body portion to a connection boundary where the first flow path and the second flow path are connected, the first flow path is partitioned into a first section, which is a section from the laser inlet to an extended end of the pressure reducing member, and a second section, which is a section from the extended end of the pressure reducing member to the particle inlet, and a length of the first section is greater than or equal to a length of the second section.

According to the particle removal apparatus according to the present disclosure, as the particle generated when machining the pattern holes of the mask assembly is effectively removed, the pattern holes may be uniformly machined when manufacturing the mask assembly.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a view illustrating a state in which a particle removal apparatus according to an example embodiment of the present disclosure is disposed above a mask assembly;

FIG. 2 is a perspective view illustrating a main body portion of FIG. 1;

FIG. 3 is a cross-sectional view illustrating a first example embodiment of the main body portion of FIG. 2;

FIG. 4 is a view illustrating an air flow in FIG. 3;

FIG. 5 is a cross-sectional view illustrating a second example embodiment of the main body portion of FIG. 2;

FIG. 6 is a view illustrating an air flow in FIG. 5;

FIG. 7 is a cross-sectional view illustrating a third example embodiment of the main body portion of FIG. 2;

FIG. 8 is a view illustrating an air flow in FIG. 7;

FIG. 9 is a cross-sectional view illustrating a fourth example embodiment of the main body portion of FIG. 2;

FIG. 10 is a view illustrating an air flow in FIG. 9;

FIG. 11 is a cross-sectional view illustrating a fifth example embodiment of the main body portion of FIG. 2; and

FIG. 12 is a view illustrating an air flow in FIG. 11.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure as defined by the claims is not limited thereto.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are illustrative examples and are not limiting.

Terms such as, for example, “first,” “second,” and the like are used to distinguish arbitrarily between the elements such terms describe, and thus these terms are not necessarily intended to indicate temporal or other prioritization of such elements. These terms are used to distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

Hereinafter, specific example embodiments will be described with reference to the accompanying drawings.

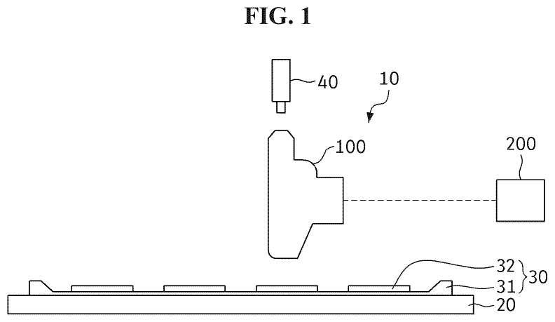

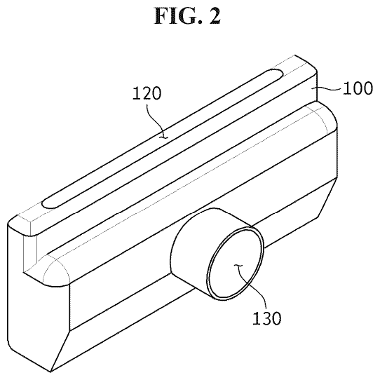

FIG. 1 is a view illustrating a state in which a particle removal apparatus 10 according to an example embodiment of the present disclosure is disposed above a mask assembly 30. FIG. 2 is a perspective view illustrating a main body portion 100 of FIG. 1.

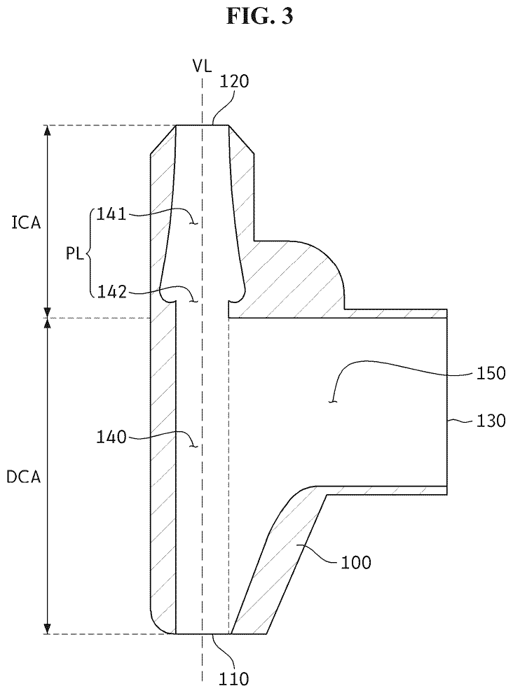

FIG. 3 is a cross-sectional view illustrating a first example embodiment of the main body portion 100 of FIG. 2.

Referring to FIGS. 1 to 3, a particle removal apparatus 10 according to a first example embodiment of the present disclosure may be disposed above a mask assembly 30 and may suck and remove particle generated in a process of machining a pattern hole of the mask assembly 30. The mask assembly 30 may include a frame 31 and a mask 32, and may be formed such that a plurality of masks 32 are arranged on the frame 31. The mask assembly 30 may be seated on a stage 20 and may be moved in a horizontal direction, and a pattern hole may be machined in the mask 32 by a laser generated from a laser generator 40 disposed above the mask assembly 30. The particle removal apparatus 10 may be disposed such that a lower portion of the particle removal apparatus 10 is adjacent to the mask assembly 30, and the laser generator 40 may be disposed above the particle removal apparatus 10. The laser generated by the laser generator 40 passes through the particle removal apparatus 10 and machines the mask assembly 30. In the process of the laser machining the pattern hole of the mask assembly 30, a large amount of particle may be generated, and the generated particle may be sucked in and removed by the particle removal apparatus 10.

The particle removal apparatus 10 may include a main body portion 100 and a particle collector 200.

The laser for machining the mask assembly 30, which is a workpiece, passes through the main body portion 100 that may suction the particle generated from the mask assembly 30. The main body portion 100 may be disposed such that a lower portion of the main body portion 100 is adjacent to an upper portion of the mask assembly 30, and the laser generator 40 may be disposed above the main body portion 100. In other words, the main body portion 100 may be disposed between the mask assembly 30 and the laser generator 40. The main body portion 100 may include a particle inlet 110, a laser inlet 120, a particle outlet 130, a first flow path 140, and a second flow path 150.

The particle inlet 110 may provide a passage through which the particle removal apparatus 10 is configured to suction the particle (or particles) generated from the mask assembly 30 into the main body portion 100. The particle inlet 110 may be formed in the lower portion of the main body portion 100 such that the particle inlet 110 is adjacent to a machining area of the mask assembly 30. The particle inlet 110 may be a long hole perforated in a lower surface of the main body portion 100 in a longitudinal direction of the main body portion 100. The particle collector 200 may apply a first suction pressure to the particle inlet 110 such that the particle generated from the mask assembly 30 is suctioned into the main body portion 100.

The laser inlet 120 may provide a passage through which the laser generated from the laser generator 40 is introduced into the main body portion 100. The laser inlet 120 may be formed in the upper portion of the main body portion 100 such that the laser inlet 120 is adjacent to the laser generator 40. The laser inlet 120 may be formed in a shape corresponding to the particle inlet 110. In other words, the laser inlet 120 may be a long hole perforated in an upper surface of the main body portion 100 in the longitudinal direction of the main body portion 100. The laser inlet 120 may be disposed on the upper surface of the main body portion 100 such that the laser inlet 120 is positioned on the same virtual vertical line VL as the particle inlet 110. The laser introduced through the laser inlet 120 may pass through the main body portion 100 through the particle inlet 110 and machine the mask assembly 30. The particle collector 200 may apply a second suction pressure to the laser inlet 120 by the particle collector 200.

The particle outlet 130 may provide a passage through which the particle suctioned into the main body portion 100 is discharged to the outside of the main body portion 100. The particle outlet 130 may be disposed on a side surface of the main body portion 100 such that the particle outlet 130 is positioned above the particle inlet 110. The particle outlet 130 may be connected to the particle collector 200, and the particle suctioned into the main body portion 100 by an operation of the particle collector 200 may pass through the particle outlet 130 and be discharged from the main body portion 100. The particle discharged from the main body portion 100 may be collected in the particle collector 200.

The first flow path 140 may connect the particle inlet 110 and the laser inlet 120. The first flow path 140 may be provided as a hole perforated along a virtual vertical line VL. In other words, the first flow path 140 may be a formed passage which penetrates through the main body portion 100 from the particle inlet 110 to the laser inlet 120. The first flow path 140 may be connected to the particle outlet 130 through the second flow path 150. The first flow path 140 may provide a passage for the laser generated from the laser generator 40 to pass through, and may provide a passage for the particle suctioned through the particle inlet 110 to flow inside the main body portion 100.

The first flow path 140 may be partitioned into a direct connection area DCA directly connected to the second flow path 150 and an indirect connection area ICA indirectly connected to the second flow path 150. The direct connection area DCA may be an area of the first flow path 140 adjacent to the particle inlet 110. For example, the direct connection area DCA may be formed across the central and lower portions of the main body portion 100 and may be formed to directly communicate with the second flow path 150. The indirect connection area ICA may be an area of the first flow path 140 adjacent to the laser inlet 120. For example, the indirect connection area ICA may be formed on the upper side of the main body portion 100. The indirect connection area ICA may be connected to the second flow path 150 through the direct connection area DCA.

A pressure reducing section PL may be formed in the first flow path 140. The pressure reducing section PL may be formed in the indirect connection area ICA of the first flow path 140. In other words, the pressure reducing section PL may be formed closer to the laser inlet 120 than the particle inlet 110. The pressure reducing section PL may reduce the second suction pressure applied to the laser inlet 120 by the particle collector 200. The pressure reducing section PL may include an expansion section 141 and a contraction section 142.

The expansion section 141 may be formed such that a cross-sectional area of the first flow path 140 gradually increases from the laser inlet 120 toward the particle inlet 110. In other words, the expansion section 141 may be formed such that the cross-sectional area of the first flow path 140 gradually increases from the upper portion to the lower portion of the main body portion 100. The expansion section 141 may be formed from the laser inlet 120 to the particle inlet 110. In other words, a cross-sectional area of the uppermost side of the first flow path 140 in the expansion section 141 may be the same as a cross-sectional area of the laser inlet 120.

The contraction section 142 may be formed consecutively with the expansion section 141. In some embodiments, the cross-sectional area of the first flow path 140 may be smaller in the contraction section 142 compared to in the expansion section 141. The cross-sectional area of the first flow path 140 in the pressure reducing section PL may be a cross-sectional area in a horizontal direction of FIG. 3.

The second flow path 150 may connect the first flow path 140 and the particle outlet 130. In other words, the second flow path 150 may connect the direct connection area DCA of the first flow path 140 and the particle outlet 130. The second flow path 150 may be a passage formed inside the main body portion 100. The second flow path 150 may provide a passage for the particle suctioned into the main body portion 100 through the particle inlet 110 to flow to the particle outlet 130.

The particle collector 200 may be a device that collects and removes solid or liquid particle floating in a gas. The particle collector 200 may be connected to the particle outlet 130 and may collect the particle discharged through the particle outlet 130.

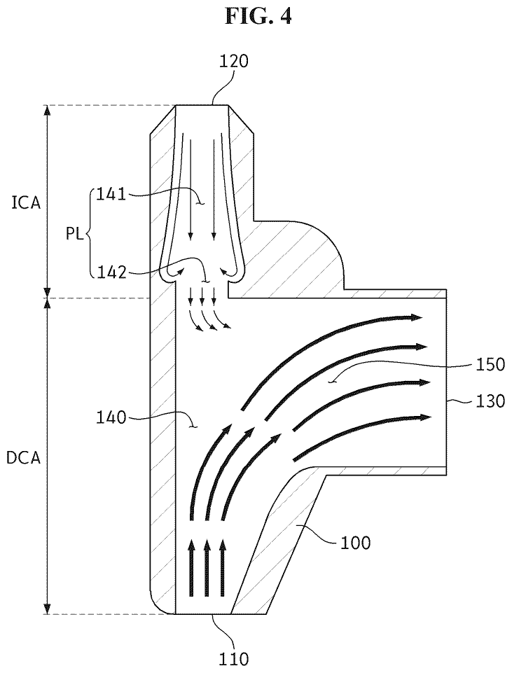

FIG. 4 is a view illustrating an air flow in FIG. 3.

Referring to FIG. 4, by operating the particle collector 200, a first suction pressure may be applied to the particle inlet 110, and a second suction pressure may be applied to the laser inlet 120. The particle generated from the mask assembly 30 may flow into the first flow path 140 through the particle inlet 110 together with the air outside the main body portion 100 by the first suction pressure. The particle flowing into the first flow path 140 may be discharged to the particle outlet 130 via the first flow path 140 and the second flow path 150. The particle discharged to the particle outlet 130 may be collected in the particle collector 200.

In some aspects, the air outside the main body portion 100 may flow into the first flow path 140 through the laser inlet 120 by the second suction pressure. The air flowing into the first flow path 140 through the laser inlet 120 passes through the pressure reducing section PL of the first flow path 140. In general, since fluid flows along a surface of a flow surface due to the Coanda effect, the air passing through the pressure reducing section PL may flow along an inner surface of the expansion section 141 and an inner surface of the contraction section 142. Air may flow along the inner surface of the expansion section 141 and then flow along the inner surface of the contraction section 142 to form a vortex. Since the vortex is formed in the air flowing into the first flow path 140 through the laser inlet 120, the second suction pressure may decrease. Since a mass flow rate of air flowing in the first flow path 140 and the second flow path 150 of the main body portion 100 is constant, the first suction pressure may increase when the second suction pressure decreases. In this way, when the second suction pressure decreases and the first suction pressure increases, the particle generated from the mask assembly 30 near the particle inlet 110 may be more efficiently suctioned into the main body portion 100. Through this, the removal of particle remaining in the mask assembly 30 becomes smooth, thereby reducing a defect occurrence rate during pattern hole machining of the mask assembly 30.

In some embodiments, in addition to such a configuration, a particle removal apparatus 10 according to a second example embodiment of the present disclosure may be provided. A second example embodiment of the present disclosure will be described with reference to the drawings.

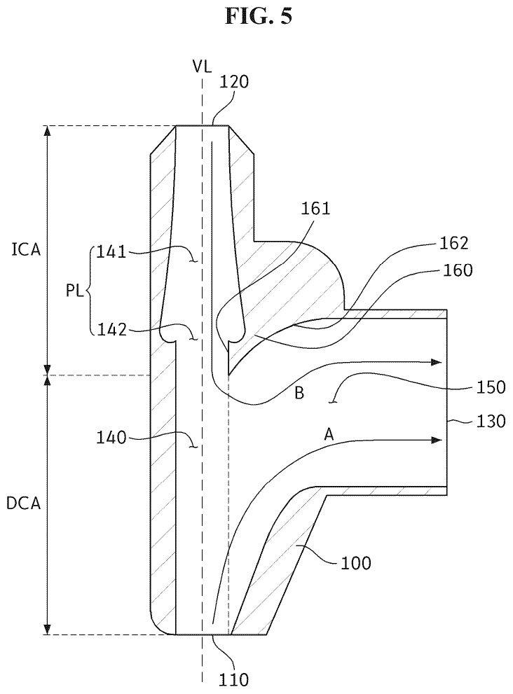

FIG. 5 is a cross-sectional view illustrating a second example embodiment of the main body portion 100 of FIG. 2.

Referring to FIG. 5, the particle removal apparatus 10 may include a main body portion 100 and a particle collector 200.

The laser for machining the mask assembly 30, which is a workpiece, passes through the main body portion 100 that may suction the particle generated from the mask assembly 30. The main body portion 100 may be disposed such that a lower portion of the main body portion 100 is adjacent to an upper portion of the mask assembly 30, and the laser generator 40 may be disposed above the main body portion 100. In other words, the main body portion 100 may be disposed between the mask assembly 30 and the laser generator 40. The main body portion 100 may include a particle inlet 110, a laser inlet 120, a particle outlet 130, a first flow path 140, and a second flow path 150.

The particle inlet 110 may provide a passage through which the particle generated from the mask assembly 30 is suctioned into the main body portion 100. The particle inlet 110 may be formed in the lower portion of the main body portion 100 such that the particle inlet 110 is adjacent to a machining area of the mask assembly 30. The particle inlet 110 may be a long hole perforated in a lower surface of the main body portion 100 in a longitudinal direction of the main body portion 100. The particle collector 200 may apply a first suction pressure to the particle inlet 110 such that the particle generated from the mask assembly 30 is suctioned into the main body portion 100.

The laser inlet 120 may provide a passage through which the laser generated from the laser generator 40 is introduced into the main body portion 100. The laser inlet 120 may be formed in the upper portion of the main body portion 100 such that the laser inlet 120 is adjacent to the laser generator 40. The laser inlet 120 may be formed in a shape corresponding to the particle inlet 110. In other words, the laser inlet 120 may be a long hole perforated in an upper surface of the main body portion 100 in the longitudinal direction of the main body portion 100. The laser inlet 120 may be disposed on the upper surface of the main body portion 100 such that the laser inlet 120 is positioned on the same virtual vertical line VL as the particle inlet 110. The laser introduced through the laser inlet 120 may pass through the main body portion 100 through the particle inlet 110 and machine the mask assembly 30. A second suction pressure may be applied to the laser inlet 120 by the particle collector 200.

The particle outlet 130 may provide a passage through which the particle suctioned into the main body portion 100 is discharged to the outside of the main body portion 100. The particle outlet 130 may be disposed on a side surface of the main body portion 100 such that the particle outlet 130 is positioned above the particle inlet 110. The particle outlet 130 may be connected to the particle collector 200, and the particle suctioned into the main body portion 100 by an operation of the particle collector 200 may pass through the particle outlet 130 and be discharged from the main body portion 100. The particle discharged from the main body portion 100 may be collected in the particle collector 200.

The first flow path 140 may connect the particle inlet 110 and the laser inlet 120. The first flow path 140 may be provided as a hole perforated along a virtual vertical line VL. In other words, the first flow path 140 may be a formed passage which penetrates through the main body portion 100 from the particle inlet 110 to the laser inlet 120. The first flow path 140 may be connected to the particle outlet 130 through the second flow path 150. The first flow path 140 may provide a passage for the laser generated from the laser generator 40 to pass through, and may provide a passage for the particle suctioned through the particle inlet 110 to flow inside the main body portion 100.

The first flow path 140 may be partitioned into a direct connection area DCA directly connected to the second flow path 150 and an indirect connection area ICA indirectly connected to the second flow path 150. The direct connection area DCA may be an area of the first flow path 140 adjacent to the particle inlet 110. For example, the direct connection area DCA may be formed across the central and lower portions of the main body portion 100 and may be formed to directly communicate with the second flow path 150. The indirect connection area ICA may be an area of the first flow path 140 adjacent to the laser inlet 120. For example, the indirect connection area ICA may be formed on the upper side of the main body portion 100. The indirect connection area ICA may be connected to the second flow path 150 through the direct connection area DCA.

A pressure reducing section PL may be formed in the first flow path 140. The pressure reducing section PL may be formed in the indirect connection area ICA of the first flow path 140. In other words, the pressure reducing section PL may be formed closer to the laser inlet 120 than the particle inlet 110. The pressure reducing section PL may reduce the second suction pressure applied to the laser inlet 120 by the particle collector 200. The pressure reducing section PL may include an expansion section 141 and a contraction section 142.

The expansion section 141 may be formed such that a cross-sectional area of the first flow path 140 gradually increases from the laser inlet 120 toward the particle inlet 110. In other words, the expansion section 141 may be formed such that the cross-sectional area of the first flow path 140 gradually increases from the upper portion to the lower portion of the main body portion 100. The expansion section 141 may be formed from the laser inlet 120 to the particle inlet 110. In other words, a cross-sectional area of the uppermost side of the first flow path 140 in the expansion section 141 may be the same as a cross-sectional area of the laser inlet 120.

The contraction section 142 is formed consecutively with the expansion section 141, and may be a section in which the cross-sectional area of the first flow path 140 is reduced compared to the cross-sectional area of the first flow path 140 in the expansion section 141. The cross-sectional area of the first flow path 140 in the pressure reducing section PL may be a cross-sectional area in a horizontal direction of FIG. 5.

The second flow path 150 may connect the first flow path 140 and the particle outlet 130. In other words, the second flow path 150 may connect the direct connection area DCA of the first flow path 140 and the particle outlet 130. The second flow path 150 may be a passage formed inside the main body portion 100. The second flow path 150 may provide a passage for the particle suctioned into the main body portion 100 through the particle inlet 110 to flow to the particle outlet 130.

A pressure reducing member 160 may be formed in the second flow path 150. The pressure reducing member 160 may reduce the second suction pressure applied to the laser inlet 120 by the particle collector 200. The pressure reducing member 160 may extend from an inner surface of the main body portion 100 forming the second flow path 150 adjacent to the laser inlet 120 to the center side of the second flow path 150. In other words, the pressure reducing member 160 may extend downward from an upper inner surface of the main body portion 100 forming the second flow path 150. The pressure reducing member 160 may extend from the inner surface of the main body portion 100 to a connection boundary where the first flow path 140 and the second flow path 150 are connected.

The pressure reducing member 160 may include a first surface 161 and a second surface 162. The first surface 161 may extend from the inner surface of the main body portion 100 along the first flow path 140 to the connection boundary where the first flow path 140 and the second flow path 150 are connected to form a portion of the first flow path 140. An end of the first surface 161 may extend toward the particle inlet 110. The second surface 162 may extend from the end of the first surface 161 to the inner surface of the main body portion 100 forming the second flow path 150. The second surface 162 may be formed as a curved surface that is concave toward the outside of the main body portion 100.

The air flowing into the main body portion 100 through the particle inlet 110 by the first suction pressure may flow along a first path A passing through the first flow path 140 and the second flow path 150, and the air flowing into the main body portion 100 through the laser inlet 120 by the second suction pressure may flow along a second path B passing through the first flow path 140 and the second flow path 150. Since the pressure reducing member 160 extends along the first flow path 140 to the connection boundary where the first flow path 140 and the second flow path 150 are connected, the second path B may be longer than the first path A.

The particle collector 200 may be a device that collects and removes solid or liquid particles floating in a gas. The particle collector 200 may be connected to the particle outlet 130 and may collect the particle discharged through the particle outlet 130.

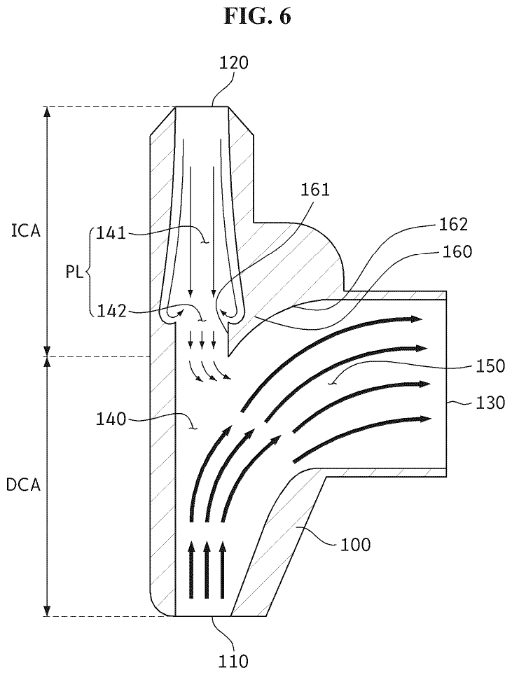

FIG. 6 is a view illustrating an air flow in FIG. 5.

Referring to FIG. 6, by operating the particle collector 200, a first suction pressure may be applied to the particle inlet 110, and a second suction pressure may be applied to the laser inlet 120. The particle generated from the mask assembly 30 may flow into the first flow path 140 through the particle inlet 110 together with the air outside the main body portion 100 by the first suction pressure. The particle flowing into the first flow path 140 may be discharged to the particle outlet 130 via the first flow path 140 and the second flow path 150. The particle discharged to the particle outlet 130 may be collected in the particle collector 200.

In some aspects, the air outside the main body portion 100 may flow into the first flow path 140 through the laser inlet 120 by the second suction pressure. The air flowing into the first flow path 140 through the laser inlet 120 passes through the pressure reducing section PL of the first flow path 140. In general, since fluid flows along a surface of a flow surface due to the Coanda effect, the air passing through the pressure reducing section PL may flow along an inner surface of the expansion section 141 and an inner surface of the contraction section 142. Air may flow along the inner surface of the expansion section 141 and then flow along the inner surface of the contraction section 142 to form a vortex. Since the vortex is formed in the air flowing into the first flow path 140 through the laser inlet 120, the second suction pressure may decrease. Since a mass flow rate of air flowing in the first flow path 140 and the second flow path 150 of the main body portion 100 is constant, the first suction pressure may increase when the second suction pressure decreases.

In some aspects, since the second path B through which the air flowing into the main body portion 100 through the laser inlet 120 by the pressure reducing member 160 flows to the particle outlet 130 is longer than the first path A through which the air flowing into the main body portion 100 through the particle inlet 110 flows to the particle outlet 130, the second suction pressure may decrease. In general, since a pressure loss of the fluid is proportional to a length along which the fluid flows, the second suction pressure may be lower than the first suction pressure.

In this way, when the second suction pressure decreases and the first suction pressure increases, the particle generated from the mask assembly 30 near the particle inlet 110 may be more efficiently suctioned into the main body portion 100. Through this, the removal of particle remaining in the mask assembly 30 becomes smooth, thereby reducing a defect occurrence rate during pattern hole machining of the mask assembly 30.

Since the second example embodiment further includes the pressure reducing member 160 than the first example embodiment, the second suction pressure of the second example embodiment may be lower than the second suction pressure of the first example embodiment. Therefore, a particle removal efficiency of the particle removal apparatus 10 according to the second example embodiment may be better than the particle removal efficiency of the particle removal apparatus 10 according to the first example embodiment.

In some embodiments, in addition to such a configuration, a particle removal apparatus 10 according to a third example embodiment of the present disclosure may be provided. A third example embodiment of the present disclosure will be described with reference to the drawings.

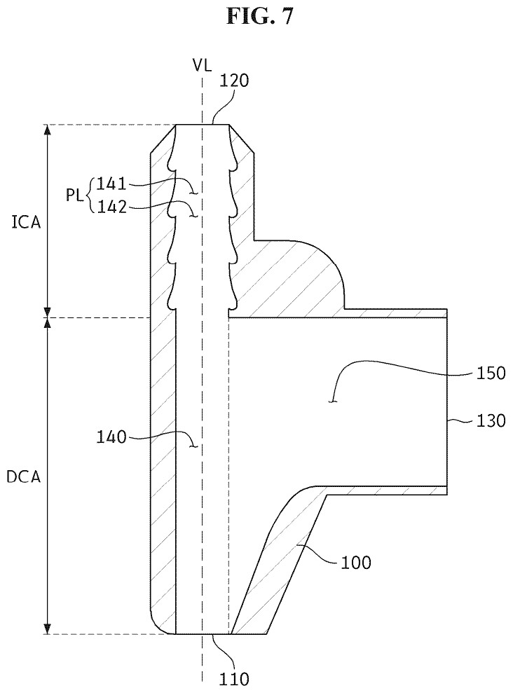

FIG. 7 is a cross-sectional view illustrating a third example embodiment of the main body portion of FIG. 2.

Referring to FIG. 7, the particle removal apparatus 10 may include a main body portion 100 and a particle collector 200.

The laser for machining the mask assembly 30, which is a workpiece, passes through the main body portion 100 that may suction the particle generated from the mask assembly 30. The main body portion 100 may be disposed such that a lower portion of the main body portion 100 is adjacent to an upper portion of the mask assembly 30, and the laser generator 40 may be disposed above the main body portion 100. In other words, the main body portion 100 may be disposed between the mask assembly 30 and the laser generator 40. The main body portion 100 may include a particle inlet 110, a laser inlet 120, a particle outlet 130, a first flow path 140, and a second flow path 150.

The particle inlet 110 may provide a passage through which the particle removal apparatus 10 may suction the particle generated from the mask assembly 30 into the main body portion 100. The particle inlet 110 may be formed in the lower portion of the main body portion 100 such that the particle inlet 110 is adjacent to a machining area of the mask assembly 30. The particle inlet 110 may be a long hole perforated in a lower surface of the main body portion 100 in a longitudinal direction of the main body portion 100. The particle collector 200 may apply a first suction pressure to the particle inlet 110 by the particle collector 200 such that the particle generated from the mask assembly 30 is suctioned into the main body portion 100.

The laser inlet 120 may provide a passage through which the laser generated from the laser generator 40 is introduced into the main body portion 100. The laser inlet 120 may be formed in the upper portion of the main body portion 100 such that the laser inlet 120 is adjacent to the laser generator 40. The laser inlet 120 may be formed in a shape corresponding to the particle inlet 110. In other words, the laser inlet 120 may be a long hole perforated in an upper surface of the main body portion 100 in the longitudinal direction of the main body portion 100. The laser inlet 120 may be disposed on the upper surface of the main body portion 100 such that the laser inlet 120 is positioned on the same virtual vertical line VL as the particle inlet 110. The laser introduced through the laser inlet 120 may pass through the main body portion 100 through the particle inlet 110 and machine the mask assembly 30. A second suction pressure may be applied to the laser inlet 120 by the particle collector 200.

The particle outlet 130 may provide a passage through which the particle suctioned into the main body portion 100 is discharged to the outside of the main body portion 100. The particle outlet 130 may be disposed on a side surface of the main body portion 100 such that the particle outlet 130 is positioned above the particle inlet 110. The particle outlet 130 may be connected to the particle collector 200, and the particle suctioned into the main body portion 100 by an operation of the particle collector 200 may pass through the particle outlet 130 and be discharged from the main body portion 100. The particle discharged from the main body portion 100 may be collected in the particle collector 200.

The first flow path 140 may connect the particle inlet 110 and the laser inlet 120. The first flow path 140 may be provided as a hole perforated along a virtual vertical line VL. In other words, the first flow path 140 may be a formed passage which penetrates through the main body portion 100 from the particle inlet 110 to the laser inlet 120. The first flow path 140 may be connected to the particle outlet 130 through the second flow path 150. The first flow path 140 may provide a passage for the laser generated from the laser generator 40 to pass through, and may provide a passage for the particle suctioned through the particle inlet 110 to flow inside the main body portion 100.

The first flow path 140 may be partitioned into a direct connection area DCA directly connected to the second flow path 150 and an indirect connection area ICA indirectly connected to the second flow path 150. The direct connection area DCA may be an area of the first flow path 140 adjacent to the particle inlet 110. For example, the direct connection area DCA may be formed across the central and lower portions of the main body portion 100 and may be formed to directly communicate with the second flow path 150. The indirect connection area ICA may be an area of the first flow path 140 adjacent to the laser inlet 120. For example, the indirect connection area ICA may be formed on the upper side of the main body portion 100. The indirect connection area ICA may be connected to the second flow path 150 through the direct connection area DCA.

A pressure reducing section PL may be formed in the first flow path 140. The pressure reducing section PL may be formed in the indirect connection area ICA of the first flow path 140. In other words, the pressure reducing section PL may be formed closer to the laser inlet 120 than the particle inlet 110. The pressure reducing section PL may reduce the second suction pressure applied to the laser inlet 120 by the particle collector 200. The pressure reducing section PL may include an expansion section 141 and a contraction section 142.

The expansion section 141 may be formed such that a cross-sectional area of the first flow path 140 gradually increases from the laser inlet 120 toward the particle inlet 110. In other words, the expansion section 141 may be formed such that the cross-sectional area of the first flow path 140 gradually increases from the upper portion to the lower portion of the main body portion 100. The expansion section 141 may be formed from the laser inlet 120 to the particle inlet 110. In other words, a cross-sectional area of the uppermost side of the first flow path 140 in the expansion section 141 may be the same as a cross-sectional area of the laser inlet 120.

The contraction section 142 is formed consecutively with the expansion section 141, and may be a section in which the cross-sectional area of the first flow path 140 is reduced compared to the cross-sectional area of the first flow path 140 in the expansion section 141. The cross-sectional area of the first flow path 140 in the pressure reducing section PL may be a cross-sectional area in a horizontal direction of FIG. 7.

The main body portion 100 may include a plurality of expansion sections 141 and contraction sections 142, and the plurality of expansion sections 141 and contraction sections 142 may be sequentially disposed alternately with each other. In other words, the plurality of expansion sections 141 and contraction sections 142 may be alternately arranged from the upper portion to the lower portion of the main body portion 100 along the first flow path 140 in the indirect connection area ICA of the first flow path 140.

The second flow path 150 may connect the first flow path 140 and the particle outlet 130. In other words, the second flow path 150 may connect the direct connection area DCA of the first flow path 140 and the particle outlet 130. The second flow path 150 may be a passage formed inside the main body portion 100. The second flow path 150 may provide a passage for the particle suctioned into the main body portion 100 through the particle inlet 110 to flow to the particle outlet 130.

The particle collector 200 may be a device that collects and removes solid or liquid particles floating in a gas. The particle collector 200 may be connected to the particle outlet 130 and may collect the particle discharged through the particle outlet 130.

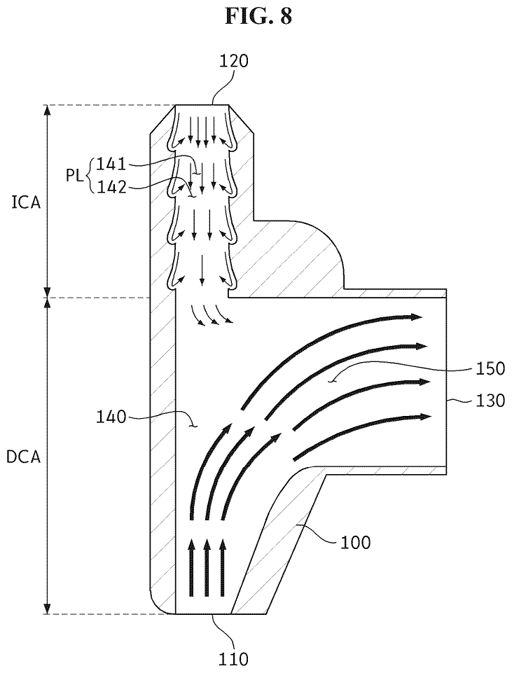

FIG. 8 is a view illustrating an air flow in FIG. 7.

Referring to FIG. 8, by operating the particle collector 200, a first suction pressure may be applied to the particle inlet 110, and a second suction pressure may be applied to the laser inlet 120. The particle generated from the mask assembly 30 may flow into the first flow path 140 through the particle inlet 110 together with the air outside the main body portion 100 by the first suction pressure. The particle flowing into the first flow path 140 may be discharged to the particle outlet 130 via the first flow path 140 and the second flow path 150. The particle discharged to the particle outlet 130 may be collected in the particle collector 200.

In some aspects, the air outside the main body portion 100 may flow into the first flow path 140 through the laser inlet 120 by the second suction pressure. The air flowing into the first flow path 140 through the laser inlet 120 passes through the pressure reducing section PL of the first flow path 140. In general, since fluid flows along a surface of a flow surface due to the Coanda effect, the air passing through the pressure reducing section PL may flow along an inner surface of the expansion section 141 and an inner surface of the contraction section 142. Air may flow along the inner surface of the expansion section 141 and then flow along the inner surface of the contraction section 142 to form a vortex. Since the plurality of expansion sections 141 and contraction sections 142 are alternately disposed in the pressure reducing section PL, a vortex may be formed in each contraction section 142. Since a plurality of vortices are formed in the air flowing into the first flow path 140 through the laser inlet 120, the second suction pressure may decrease. Since a mass flow rate of air flowing in the first flow path 140 and the second flow path 150 of the main body portion 100 is constant, the first suction pressure may increase when the second suction pressure decreases. In this way, when the second suction pressure decreases and the first suction pressure increases, the particle generated from the mask assembly 30 near the particle inlet 110 may be more efficiently suctioned into the main body portion 100. Through this, the removal of particle remaining in the mask assembly 30 becomes smooth, thereby reducing a defect occurrence rate during pattern hole machining of the mask assembly 30.

In the third example embodiment, since the pressure reducing section PL further includes the plurality of expansion sections 141 and contraction sections 142 compared to the first example embodiment, the second suction pressure of the third example embodiment may be smaller than the second suction pressure of the first example embodiment. Therefore, a particle removal efficiency of the particle removal apparatus 10 according to the third example embodiment may be better than the particle removal efficiency of the particle removal apparatus 10 according to the first example embodiment.

In some embodiments, in addition to such a configuration, a particle removal apparatus 10 according to a fourth example embodiment of the present disclosure may be provided. A fourth example embodiment of the present disclosure will be described with reference to the drawings.

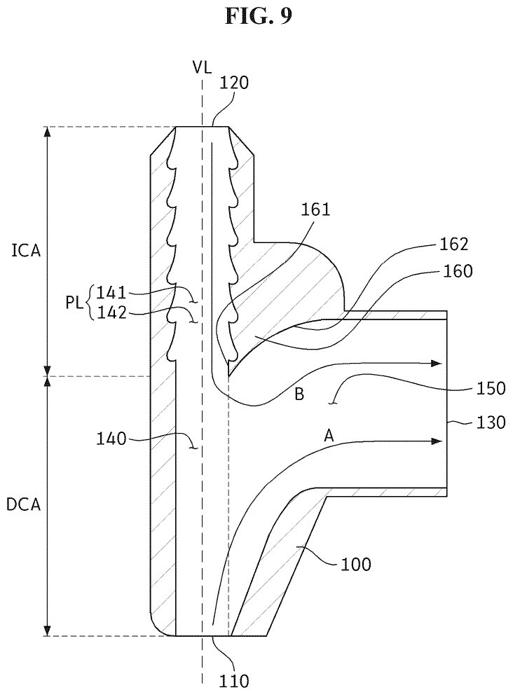

FIG. 9 is a cross-sectional view illustrating a fourth example embodiment of the main body portion of FIG. 2.

Referring to FIG. 9, the particle removal apparatus 10 may include a main body portion 100 and a particle collector 200.

The laser for machining the mask assembly 30, which is a workpiece, passes through the main body portion 100 that may suction the particle generated from the mask assembly 30. The main body portion 100 may be disposed such that a lower portion of the main body portion 100 is adjacent to an upper portion of the mask assembly 30, and the laser generator 40 may be disposed above the main body portion 100. In other words, the main body portion 100 may be disposed between the mask assembly 30 and the laser generator 40. The main body portion 100 may include a particle inlet 110, a laser inlet 120, a particle outlet 130, a first flow path 140, and a second flow path 150.

The particle inlet 110 may provide a passage through which the particle generated from the mask assembly 30 is suctioned into the main body portion 100. The particle inlet 110 may be formed in the lower portion of the main body portion 100 such that the particle inlet 110 is adjacent to a machining area of the mask assembly 30. The particle inlet 110 may be a long hole perforated in a lower surface of the main body portion 100 in a longitudinal direction of the main body portion 100. The particle collector 200 may apply a first suction pressure to the particle inlet 110 such that the particle generated from the mask assembly 30 is suctioned into the main body portion 100.

The laser inlet 120 may provide a passage through which the laser generated from the laser generator 40 is introduced into the main body portion 100. The laser inlet 120 may be formed in the upper portion of the main body portion 100 such that the laser inlet 120 is adjacent to the laser generator 40. The laser inlet 120 may be formed in a shape corresponding to the particle inlet 110. In other words, the laser inlet 120 may be a long hole perforated in an upper surface of the main body portion 100 in the longitudinal direction of the main body portion 100. The laser inlet 120 may be disposed on the upper surface of the main body portion 100 such that the laser inlet 120 is positioned on the same virtual vertical line VL as the particle inlet 110. The laser introduced through the laser inlet 120 may pass through the main body portion 100 through the particle inlet 110 and machine the mask assembly 30. A second suction pressure may be applied to the laser inlet 120 by the particle collector 200.

The particle outlet 130 may provide a passage through which the particle suctioned into the main body portion 100 is discharged to the outside of the main body portion 100. The particle outlet 130 may be disposed on a side surface of the main body portion 100 such that the particle outlet 130 is positioned above the particle inlet 110. The particle outlet 130 may be connected to the particle collector 200, and the particle suctioned into the main body portion 100 by an operation of the particle collector 200 may pass through the particle outlet 130 and be discharged from the main body portion 100. The particle discharged from the main body portion 100 may be collected in the particle collector 200.

The first flow path 140 may connect the particle inlet 110 and the laser inlet 120. The first flow path 140 may be provided as a hole perforated along a virtual vertical line VL. In other words, the first flow path 140 may be a formed passage which penetrates through the main body portion 100 from the particle inlet 110 to the laser inlet 120. The first flow path 140 may be connected to the particle outlet 130 through the second flow path 150. The first flow path 140 may provide a passage for the laser generated from the laser generator 40 to pass through, and may provide a passage for the particle suctioned through the particle inlet 110 to flow inside the main body portion 100.

The first flow path 140 may be partitioned into a direct connection area DCA directly connected to the second flow path 150 and an indirect connection area ICA indirectly connected to the second flow path 150. The direct connection area DCA may be an area of the first flow path 140 adjacent to the particle inlet 110. For example, the direct connection area DCA may be formed across the central and lower portions of the main body portion 100 and may be formed to directly communicate with the second flow path 150. The indirect connection area ICA may be an area of the first flow path 140 adjacent to the laser inlet 120. For example, the indirect connection area ICA may be formed on the upper side of the main body portion 100. The indirect connection area ICA may be connected to the second flow path 150 through the direct connection area DCA.

A pressure reducing section PL may be formed in the first flow path 140. The pressure reducing section PL may be formed in the indirect connection area ICA of the first flow path 140. In other words, the pressure reducing section PL may be formed closer to the laser inlet 120 than the particle inlet 110. The pressure reducing section PL may reduce the second suction pressure applied to the laser inlet 120 by the particle collector 200. The pressure reducing section PL may include an expansion section 141 and a contraction section 142.

The expansion section 141 may be formed such that a cross-sectional area of the first flow path 140 gradually increases from the laser inlet 120 toward the particle inlet 110. In other words, the expansion section 141 may be formed such that the cross-sectional area of the first flow path 140 gradually increases from the upper portion to the lower portion of the main body portion 100. The expansion section 141 may be formed from the laser inlet 120 to the particle inlet 110. In other words, a cross-sectional area of the uppermost side of the first flow path 140 in the expansion section 141 may be the same as a cross-sectional area of the laser inlet 120.

The contraction section 142 is formed consecutively with the expansion section 141, and may be a section in which the cross-sectional area of the first flow path 140 is reduced compared to the cross-sectional area of the first flow path 140 in the expansion section 141. The cross-sectional area of the first flow path 140 in the pressure reducing section PL may be a cross-sectional area in a horizontal direction of FIG. 9.

A plurality of expansion sections 141 and contraction sections 142 are provided, and the plurality of expansion sections 141 and contraction sections 142 may be sequentially disposed alternately with each other. In other words, the plurality of expansion sections 141 and contraction sections 142 may be alternately arranged from the upper portion to the lower portion of the main body portion 100 along the first flow path 140 in the indirect connection area ICA of the first flow path 140.

The second flow path 150 may connect the first flow path 140 and the particle outlet 130. In other words, the second flow path 150 may connect the direct connection area DCA of the first flow path 140 and the particle outlet 130. The second flow path 150 may be a passage formed inside the main body portion 100. The second flow path 150 may provide a passage for the particle suctioned into the main body portion 100 through the particle inlet 110 to flow to the particle outlet 130.

A pressure reducing member 160 may be formed in the second flow path 150. The pressure reducing member 160 may reduce the second suction pressure applied to the laser inlet 120 by the particle collector 200. The pressure reducing member 160 may extend from an inner surface of the main body portion 100 forming the second flow path 150 adjacent to the laser inlet 120 to the center side of the second flow path 150. In other words, the pressure reducing member 160 may extend downward from an upper inner surface of the main body portion 100 forming the second flow path 150. The pressure reducing member 160 may extend from the inner surface of the main body portion 100 to a connection boundary where the first flow path 140 and the second flow path 150 are connected.

The pressure reducing member 160 may include a first surface 161 and a second surface 162. The first surface 161 may extend from the inner surface of the main body portion 100 along the first flow path 140 to the connection boundary where the first flow path 140 and the second flow path 150 are connected to form a portion of the first flow path 140. An end of the first surface 161 may extend toward the particle inlet 110. The second surface 162 may extend from the end of the first surface 161 to the inner surface of the main body portion 100 forming the second flow path 150. The second surface 162 may be a curved surface. For example, the second surface 162 may be formed as a curved surface that is concave toward the outside of the main body portion 100. Since the first surface 161 of the pressure reducing member 160 extends along the first flow path 140 to the connection boundary where the first flow path 140 and the second flow path 150 are connected, the indirect connection area ICA of the first flow path 140 may be a section from the laser inlet 120 to an extended end of the first surface 161, and the direct connection area DCA of the first flow path 140 may be a section from the extended end of the first surface 161 to the particle inlet 110. A length of the indirect connection area ICA of the first flow path 140 may be greater than or equal to a length of the direct connection area DCA. In some embodiments, the indirect connection area ICA may be implemented such that the maximum length of the indirect connection area ICA does not exceed twice the length of the direct connection arca DCA.

The air flowing into the main body portion 100 through the particle inlet 110 by the first suction pressure may flow along a first path A passing through the first flow path 140 and the second flow path 150, and the air flowing into the main body portion 100 through the laser inlet 120 by the second suction pressure may flow along a second path B passing through the first flow path 140 and the second flow path 150. Since the pressure reducing member 160 extends along the first flow path 140 to the connection boundary where the first flow path 140 and the second flow path 150 are connected, the second path B may be longer than the first path A.

The particle collector 200 may be a device that collects and removes solid or liquid particles floating in a gas. The particle collector 200 may be connected to the particle outlet 130 and may collect the particle discharged through the particle outlet 130.

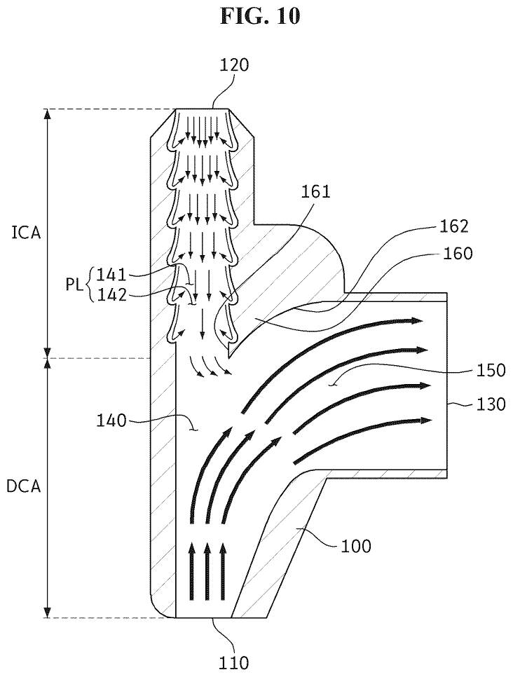

FIG. 10 is a view illustrating an air flow in FIG. 9.

Referring to FIG. 10, by operating the particle collector 200, a first suction pressure may be applied to the particle inlet 110, and a second suction pressure may be applied to the laser inlet 120. The particle generated from the mask assembly 30 may flow into the first flow path 140 through the particle inlet 110 together with the air outside the main body portion 100 by the first suction pressure. The particle flowing into the first flow path 140 may be discharged to the particle outlet 130 via the first flow path 140 and the second flow path 150. The particle discharged to the particle outlet 130 may be collected in the particle collector 200.

In some aspects, the air outside the main body portion 100 may flow into the first flow path 140 through the laser inlet 120 by the second suction pressure. The air flowing into the first flow path 140 through the laser inlet 120 passes through the pressure reducing section PL of the first flow path 140. In general, since fluid flows along a surface of a flow surface due to the Coanda effect, the air passing through the pressure reducing section PL may flow along an inner surface of the expansion section 141 and an inner surface of the contraction section 142. Air may flow along the inner surface of the expansion section 141 and then flow along the inner surface of the contraction section 142 to form a vortex. Since the plurality of expansion sections 141 and contraction sections 142 are alternately disposed in the pressure reducing section PL, a vortex may be formed in each contraction section 142. Since a plurality of vortices are formed in the air flowing into the first flow path 140 through the laser inlet 120, the second suction pressure may decrease. Since a mass flow rate of air flowing in the first flow path 140 and the second flow path 150 of the main body portion 100 is constant, the first suction pressure may increase when the second suction pressure decreases.

In some aspects, since the second path B through which the air flowing into the main body portion 100 through the laser inlet 120 by the pressure reducing member 160 flows to the particle outlet 130 is longer than the first path A through which the air flowing into the main body portion 100 through the particle inlet 110 flows to the particle outlet 130, the second suction pressure may decrease. In general, since a pressure loss of the fluid is proportional to a length along which the fluid flows, the second suction pressure may be lower than the first suction pressure.

In this way, when the second suction pressure decreases and the first suction pressure increases, the particle generated from the mask assembly 30 near the particle inlet 110 may be more efficiently suctioned into the main body portion 100. Through this, the removal of particle remaining in the mask assembly 30 becomes smooth, thereby reducing a defect occurrence rate during pattern hole machining of the mask assembly 30.

Since the fourth example embodiment further includes the pressure reducing member 160 than the third example embodiment, the second suction pressure of the fourth example embodiment may be lower than the second suction pressure of the third example embodiment. Therefore, a particle removal efficiency of the particle removal apparatus 10 according to the fourth example embodiment may be better than the particle removal efficiency of the particle removal apparatus 10 according to the third example embodiment.

In some embodiments, in addition to such a configuration, a particle removal apparatus 10 according to a fifth example embodiment of the present disclosure may be provided. A fifth example embodiment of the present disclosure will be described with reference to the drawings.

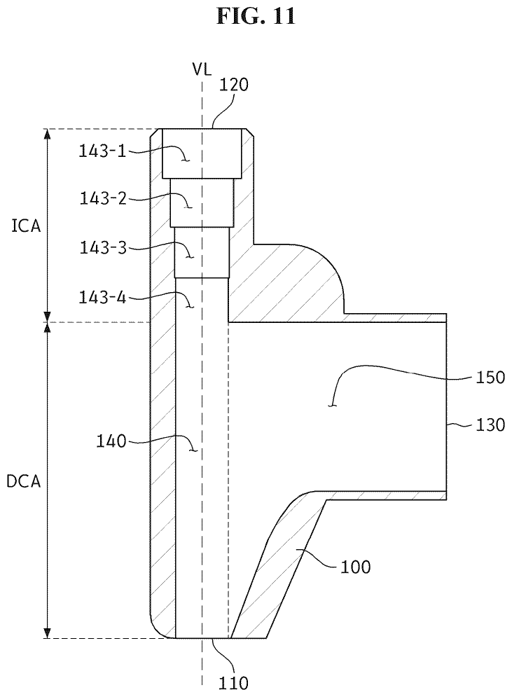

FIG. 11 is a cross-sectional view illustrating a fifth example embodiment of the main body portion of FIG. 2.

Referring to FIG. 11, the particle removal apparatus 10 may include a main body portion 100 and a particle collector 200.

The laser for machining the mask assembly 30, which is a workpiece, passes through the main body portion 100 that may suction the particle generated from the mask assembly 30. The main body portion 100 may be disposed such that a lower portion of the main body portion 100 is adjacent to an upper portion of the mask assembly 30, and the laser generator 40 may be disposed above the main body portion 100. In other words, the main body portion 100 may be disposed between the mask assembly 30 and the laser generator 40. The main body portion 100 may include a particle inlet 110, a laser inlet 120, a particle outlet 130, a first flow path 140, and a second flow path 150.

The particle inlet 110 may provide a passage through which the particle generated from the mask assembly 30 is suctioned into the main body portion 100. The particle inlet 110 may be formed in the lower portion of the main body portion 100 such that the particle inlet 110 is adjacent to a machining area of the mask assembly 30. The particle inlet 110 may be a long hole perforated in a lower surface of the main body portion 100 in a longitudinal direction of the main body portion 100. The particle collector 200 may apply a first suction pressure to the particle inlet 110 such that the particle generated from the mask assembly 30 is suctioned into the main body portion 100.

The laser inlet 120 may provide a passage through which the laser generated from the laser generator 40 is introduced into the main body portion 100. The laser inlet 120 may be formed in the upper portion of the main body portion 100 such that the laser inlet 120 is adjacent to the laser generator 40. The laser inlet 120 may be formed in a shape corresponding to the particle inlet 110. In other words, the laser inlet 120 may be a long hole perforated in an upper surface of the main body portion 100 in the longitudinal direction of the main body portion 100. The laser inlet 120 may be disposed on the upper surface of the main body portion 100 such that the laser inlet 120 is positioned on the same virtual vertical line VL as the particle inlet 110. The laser introduced through the laser inlet 120 may pass through the main body portion 100 through the particle inlet 110 and machine the mask assembly 30. A second suction pressure may be applied to the laser inlet 120 by the particle collector 200.

The particle outlet 130 may provide a passage through which the particle suctioned into the main body portion 100 is discharged to the outside of the main body portion 100. The particle outlet 130 may be disposed on a side surface of the main body portion 100 such that the particle outlet 130 is positioned above the particle inlet 110. The particle outlet 130 may be connected to the particle collector 200, and the particle suctioned into the main body portion 100 by an operation of the particle collector 200 may pass through the particle outlet 130 and be discharged from the main body portion 100. The particle discharged from the main body portion 100 may be collected in the particle collector 200.

The first flow path 140 may connect the particle inlet 110 and the laser inlet 120. The first flow path 140 may be provided as a hole perforated along a virtual vertical line VL. In other words, the first flow path 140 may be a formed passage which penetrates through the main body portion 100 from the particle inlet 110 to the laser inlet 120. The first flow path 140 may be connected to the particle outlet 130 through the second flow path 150. The first flow path 140 may provide a passage for the laser generated from the laser generator 40 to pass through, and may provide a passage for the particle suctioned through the particle inlet 110 to flow inside the main body portion 100.

The first flow path 140 may be partitioned into a direct connection area DCA directly connected to the second flow path 150 and an indirect connection area ICA indirectly connected to the second flow path 150. The direct connection area DCA may be an area of the first flow path 140 adjacent to the particle inlet 110. For example, the direct connection area DCA may be formed across the central and lower portions of the main body portion 100 and may be formed to directly communicate with the second flow path 150. The indirect connection area ICA may be an area of the first flow path 140 adjacent to the laser inlet 120. For example, the indirect connection area ICA may be formed on the upper side of the main body portion 100. The indirect connection area ICA may be connected to the second flow path 150 through the direct connection area DCA.

A pressure reducing section may be formed in the first flow path 140. The pressure reducing section may be formed in the indirect connection area ICA of the first flow path 140. In other words, the pressure reducing section may be formed closer to the laser inlet 120 than the particle inlet 110. The pressure reducing section may reduce the second suction pressure applied to the laser inlet 120 by the particle collector 200. The pressure reducing section may be formed of a plurality of sections having different respective cross-sectional areas. For example, portions (corresponding to the plurality of sections) of the first flow path 140 may have different respective cross-sectional areas. The plurality of sections may include a first section 143-1, a second section 143-2, a third section 143-3, and a fourth section 143-4.

The first section 143-1 may be formed in a downward direction from the laser inlet 120 along the first flow path 140. A cross-sectional area of the first flow path 140 in the first section 143-1 may be the same as a cross-sectional area of the laser inlet 120.

The second section 143-2 may be formed consecutively with the first section 143-1. In other words, the second section 143-2 may be formed in a downward direction from a lower portion of the first section 143-1 along the first flow path 140. A cross-sectional area of the first flow path 140 in the second section 143-2 may be smaller than the cross-sectional area of the first flow path 140 in the first section 143-1.

The third section 143-3 may be formed consecutively with the second section 143-2. In other words, the third section 143-3 may be formed in a downward direction from a lower portion of the second section 143-2 along the first flow path 140. A cross-sectional area of the first flow path 140 in the third section 143-3 may be smaller than the cross-sectional area of the first flow path 140 in the second section 143-2.

The fourth section 143-4 may be formed consecutively with the third section 143-3. In other words, the fourth section 143-4 may be formed in a downward direction from a lower portion of the third section 143-3 along the first flow path 140. A cross-sectional area of the first flow path 140 in the fourth section 143-4 may be smaller than the cross-sectional area of the first flow path 140 in the third section 143-3.

The cross-sectional area of the first flow path 140 in the pressure reducing section may be a cross-sectional area in a horizontal direction of FIG. 11.

The second flow path 150 may connect the first flow path 140 and the particle outlet 130. In other words, the second flow path 150 may connect the direct connection area DCA of the first flow path 140 and the particle outlet 130. The second flow path 150 may be a passage formed inside the main body portion 100. The second flow path 150 may provide a passage for the particle suctioned into the main body portion 100 through the particle inlet 110 to flow to the particle outlet 130.

The particle collector 200 may be a device that collects and removes solid or liquid particles floating in a gas. The particle collector 200 may be connected to the particle outlet 130 and may collect the particle discharged through the particle outlet 130.

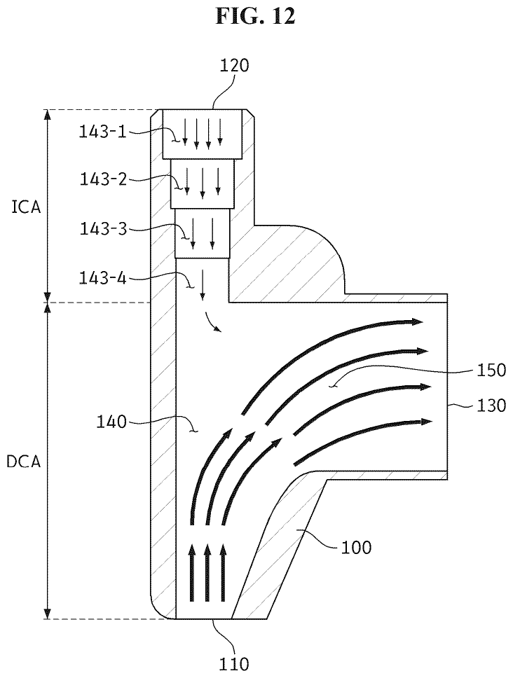

FIG. 12 is a view illustrating an air flow in FIG. 11.

Referring to FIG. 12, by operating the particle collector 200, a first suction pressure may be applied to the particle inlet 110, and a second suction pressure may be applied to the laser inlet 120. The particle generated from the mask assembly 30 may flow into the first flow path 140 through the particle inlet 110 together with the air outside the main body portion 100 by the first suction pressure. The particle flowing into the first flow path 140 may be discharged to the particle outlet 130 via the first flow path 140 and the second flow path 150. The particle discharged to the particle outlet 130 may be collected in the particle collector 200.

In some aspects, the air outside the main body portion 100 may flow into the first flow path 140 through the laser inlet 120 by the second suction pressure. The air flowing into the first flow path 140 through the laser inlet 120 passes through the pressure reducing section of the first flow path 140. In general, in fluids, a pressure loss occurs in proportion to a difference in cross-sectional area of a flow path through which the fluid flows. Therefore, since the pressure loss occurs while the air passing through the pressure reducing section sequentially passes through the first section 143-1, the second section 143-2, the third section 143-3, and the fourth section 143-4, the second suction pressure may decrease. Since a mass flow rate of air flowing in the first flow path 140 and the second flow path 150 of the main body portion 100 is constant, the first suction pressure may increase when the second suction pressure decreases. In this way, when the second suction pressure decreases and the first suction pressure increases, the particle generated from the mask assembly 30 near the particle inlet 110 may be more efficiently suctioned into the main body portion 100. Through this, the removal of particle remaining in the mask assembly 30 becomes smooth, thereby reducing a defect occurrence rate during pattern hole machining of the mask assembly 30.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A particle removal apparatus comprising:
a main body portion through which a laser for machining a workpiece passes and through which a particle generated from machining the workpiece is suctioned; and
a particle collector connected to the main body portion,
wherein:
the main body portion comprises:
a particle inlet through which the particle removal apparatus is configured to suction the particle;
a laser inlet through which the laser passes;
a particle outlet through which the particle removal apparatus is configured to discharge the particle suctioned into the main body portion;
a first flow path connecting the particle inlet and the laser inlet; and
a second flow path connecting the first flow path and the particle outlet,
wherein:
the particle collector is connected to the particle outlet and is configured to apply a first suction pressure to the particle inlet and a second suction pressure to the laser inlet, and
the first flow path comprises a pressure reducing section configured to reduce the second suction pressure.

2. The particle removal apparatus of claim 1, wherein the pressure reducing section comprises:
an expansion section in which a cross-sectional area of the first flow path gradually increases from the laser inlet toward the particle inlet, and
a contraction section formed consecutively with the expansion section, wherein the cross-sectional area of the first flow path is smaller in the contraction section compared to in the expansion section.

3. The particle removal apparatus of claim 2, further comprising a plurality of expansion sections and contraction sections,
wherein the plurality of expansion sections and contraction sections are sequentially disposed alternately with each other.

4. The particle removal apparatus of claim 1, wherein:
the pressure reducing section comprises a plurality of sections, and
the plurality of sections are sequentially disposed from the laser inlet toward the particle inlet.

5. The particle removal apparatus of claim 4, wherein the plurality of sections have different respective cross-sectional areas.

6. The particle removal apparatus of claim 5, wherein a cross-sectional area of the first flow path in a section closest to the particle inlet among the plurality of sections is smaller than a cross-sectional area of the first flow path in a section closest to the laser inlet.

7. The particle removal apparatus of claim 5, wherein a cross-sectional area of the first flow path in a section closest to the laser inlet among the plurality of sections is the same as a cross-sectional area of the laser inlet.

8. The particle removal apparatus of claim 1, wherein the pressure reducing section is closer to the laser inlet than the particle inlet.

9. The particle removal apparatus of claim 1, wherein:
the first flow path is partitioned into:
a direct connection area directly connected to the second flow path; and
an indirect connection area indirectly connected to the second flow path through the direct connection area, and
the pressure reducing section is disposed in the indirect connection area.

10. The particle removal apparatus of claim 1, wherein the second flow path comprises a pressure reducing member configured to reduce the second suction pressure.

11. The particle removal apparatus of claim 10, wherein:
air outside the main body portion flows into the main body portion through the particle inlet by the first suction pressure, and the particle removal apparatus is configured to discharge the air flowing into the main body portion through the particle inlet to the particle outlet, through a first path passing through the first flow path and the second flow path,
air outside the main body portion flows into the main body portion through the laser inlet by the second suction pressure, and the particle removal apparatus is configured to discharge the air flowing into the main body portion through the laser inlet to the particle outlet, through a second path passing through the first flow path and the second flow path, and
the pressure reducing member extends from an inner surface of the main body portion forming the second flow path to a connection boundary where the first flow path and the second flow path are connected such that the second path is longer than the first path.

12. The particle removal apparatus of claim 11, wherein the pressure reducing member extends from an inner surface of the main body portion forming the second flow path, adjacent to the laser inlet.

13. The particle removal apparatus of claim 11, wherein:
the pressure reducing member comprises:
a first surface forming a portion of the first flow path; and
a second surface forming a portion of the second flow path, and
the first surface extends such that an end of the pressure reducing member faces the particle inlet.

14. The particle removal apparatus of claim 13, wherein the second surface extends from the end of the first surface to the inner surface of the main body portion forming the second flow path.

15. The particle removal apparatus of claim 14, wherein the second surface is a curved surface.

16. The particle removal apparatus of claim 15, wherein the second surface is concavely formed toward an outside of the main body portion.

17. The particle removal apparatus of claim 1, wherein the laser inlet is positioned on a same virtual vertical line as the particle inlet.

18. The particle removal apparatus of claim 17, wherein:
the particle inlet is disposed in a lower portion of the main body portion, and
the laser inlet is disposed in an upper portion of the main body portion.

19. The particle removal apparatus of claim 18, wherein the particle outlet is disposed in a higher position than the particle inlet in the main body portion.

20. The particle removal apparatus of claim 1, wherein:
the second flow path comprises a pressure reducing member configured to reduce the second suction pressure,
the pressure reducing member extends from an inner surface of the main body portion to a connection boundary where the first flow path and the second flow path are connected,
the first flow path is partitioned into:
a first section, which is a section from the laser inlet to an extended end of the pressure reducing member; and
a second section, which is a section from the extended end of the pressure reducing member to the particle inlet, and
a length of the first section is greater than or equal to a length of the second section.
